(19) United States
(12) Patent Application Publication
(10) Pub. No.: US 2011/0025466 A1
(43) Pub. Date: Feb. 3, 2011

(54) ELECTRONIC TAG

(75) Inventor: Kate Stone, Cambridgeshire (GB)

Correspondence Address: MCCARTER & ENGLISH, LLP BOSTON, 265 Franklin Street, Boston, MA, 02110, US

(73) Assignee: NOVALIA LTD., Cambridge (GB)

(21) Appl. No.: 12/809,877

(22) PCT Filed: Dec. 19, 2008
(86) PCT No.: PCT/GB08/51220

§ 371 Date: Sep. 27, 2010

(30) Foreign Application Priority Data
Dec. 21, 2007 (GB) 0724969.1

(51) Int. Cl. G06K 7/01; G06K 19/077; H05K 13/00

(52) U.S. Cl. 340/10.1; 235/492; 29/592.1

(57) ABSTRACT

An electronic tag has a plurality of elongate conductive tracks (10) extending in a first longitudinal direction (11) and spaced apart along a second, transverse direction (12). Each track includes relatively wide and relatively narrow portions (13, 14). The plurality of conductive tracks includes at least one pair (16) of tracks providing at least one data-encoding section (17) in which a portion (14) of one track is relatively narrow and a corresponding portion (13) of the other track is relatively wide. This can be used to encode data bits ‘0’ and ‘1’. Data can be read from the data-encoding section by crossing a drive line over each track in the data-encoding section and applying a time-varying signal to the drive line. The regions of cross over form capacitive elements whose relative magnitude can be determined using a capacitance bridge.

### FIELD OF THE INVENTION

The present invention relates to an electronic tag.

### BACKGROUND

Manufacturers and suppliers of branded or high-value products often wish to use measures that allow them and/or consumers to determine whether a particular product is genuine or counterfeit. One well-known example of such a measure is a hologram. Manufactures may also wish to employ measures which allows them, but not the consumer, to identify an item, for example for tracking stock or covertly identifying counterfeits.

An electronic tag, such as that described in GB-A-2429111, may be used for these purposes. The electronic tag has first and second sets of parallel tracks which cross to form a grid. Logical states ‘0’ and ‘1’ may be encoded in the tag during manufacture by arranging for each pair of crossing tracks either to be electrically connected or not connected. Data is read out from the tag by measuring resistances between each pair of crossing tracks.

A tag having n-rows and m-column can encode up to (n×m)-bits. However, not all of these bits can be distinguished due to the fact that two tracks that should be isolated from each other may in fact be connected via a parallel conduction path through other connected tracks. If a reader has poor sensitivity, then it may not be possible to determine whether two tracks are directly connected or whether they are connected via a parallel path.

The present invention seeks to provide an improved electronic tag.

### SUMMARY

According to the present invention there is provided an electronic tag comprising a plurality of elongate conductive tracks extending in a first longitudinal direction and spaced apart along a second, transverse direction, each track including relatively wide and relatively narrow portions, the plurality of conductive tracks including at least one pair of conductive tracks providing at least one data-encoding section in which a portion of one track is relatively narrow and a corresponding portion of the other track is relatively wide.

By choosing which of the tracks in a pair is narrow in a data-encoding section, two states can be defined for example ‘0’=track 1 is narrow and track 2 is wide and ‘1’=track 1 is wide and track 2 is narrow. Since the characteristics of the two lines can be compared against each other using a difference measurement, this can make it easier to distinguish between the two states.

The at least one pair of conductive tracks may be adjacent. The conductive tracks may comprise conductive ink.

The plurality of conductive tracks may comprise at least two pairs of conductive tracks. The plurality of conductive tracks may comprise at least four pairs of conductive tracks.

The width of the relatively wide portion may be at least 10 times the width of the relatively narrow portion. The relatively narrow portion may have a width no more than 500 μm.

The at least one pair of conductive tracks, e.g. each pair, may be configured to provide at least two data-encoding sections, for example three, four or five data-encoding sections.

Each track may include at least one further portion having a width different from the relatively wide and narrow portions.

According to a second aspect of the present invention there is provided a product or packaging for a product having a surface, wherein the surface supports the electronic tag.

According to a third aspect of the present invention there is provided a device for reading an electronic tag comprising a substrate extending in first and second transverse directions, at least one elongate conductive line supported on the substrate and extending in the second direction, a plurality of electrodes supported on the substrate and spaced along the second direction and spaced from the at least one conductive line in the first direction, the plurality of electrodes including at least one pair of electrodes, a signal generator arranged to apply a time-varying signal to the at least one elongate conductive line and a circuit for receiving a respective signals from each electrode and to output a signal dependent upon a difference between the signals.

The device may comprise at least two elongate conductive lines, supported on the substrate, extending in the second direction. The device may comprise three, four or five elongate conductive lines, supported on the substrate, extending in the second direction.

The device may comprise switching means configured to apply the time-varying signal to the conductive lines in sequence.

The device may comprise means for applying a respective time-varying signal to each conductive line each time-varying signal having a different frequency. The signal applying means may be a frequency divider or a plurality of frequency sources. The circuit may be arranged to measure more than one signal component between each electrode of the pair of electrodes, each signal component having a different frequency.

According to a fourth aspect of the present invention there is provided a method of fabricating an electronic tag comprising providing a plurality of elongate conductive tracks extending in a first, longitudinal direction and spaced apart along a second, transverse direction, each track including relatively wide and relatively narrow portions, the plurality of conductive tracks including at least one pair of conductive tracks and arranging the at least one pair of conductive tracks to provide at least one data-encoding section in which a portion of one track is relatively narrow and a corresponding portion of the other track is relatively wide.

Providing the plurality of conductive tracks may comprise printing the plurality of elongate conductive tracks using a conductive ink.

According to a fifth aspect of the present invention there is provided a method of reading an electronic tag comprising a plurality of elongate conductive tracks extending in a first direction and spaced apart along a second, transverse direction, the plurality of conductive tracks including at least one pair of conductive tracks providing at least one data-encoding section in which a portion of one track is relatively narrow and a corresponding portion of the other track is relatively wide, the method comprising placing at least one elongate conductive line extending in the second direction over the at least a pair of conductive tracks inside the data-encoding section, placing at least two electrodes over the conductive tracks outside the data-encoding section, applying a time varying signal to the elongate conductive line and determining an output signal dependent upon a difference between signals taken from the two electrodes.

According to a sixth aspect of the present invention there is provided a method of reading an electronic tag comprising a plurality of elongate conductive tracks extending in a first longitudinal direction and spaced apart along a second, transverse direction, the plurality of conductive tracks including at least one pair of conductive tracks providing at least one data-encoding section in which a portion of one track is relatively narrow and a corresponding portion of the other track is relatively wide, the method comprising placing at least one elongate conductive line extending in the second direction over the at least a pair of conductive tracks one side of the data-encoding section, placing at least two electrodes over the conductive tracks on the other side of the data-encoding section such that the data-encoding section lies between the at least one elongate conductive line and the electrodes, applying a time varying signal to the elongate conductive line and determining an output signal dependent upon a difference between signals taken from the two electrodes.

The method may comprise keeping a tag reader stationary with respect to the tag.

### BRIEF DESCRIPTION OF THE DRAWINGS

Embodiments of the present invention will now be described, by way of example, with reference to the accompanying drawings in which:

FIG. 1 is a perspective view of an item carrying a tag in accordance with the present invention;

FIG. 2 is a plan view of a tag in accordance with the present invention;

FIG. 2a is an enlarged partial plan view of the tag shown in FIG. 2;

FIG. 3 is a plan view of the tag shown in FIG. 2, together with a set of driving lines and reading electrodes of an overlying reader;

FIG. 4 is a partial sectional view showing a tag and an overlying reader;

FIG. 5 is a circuit diagram of the tag shown in FIG. 2, a driving module and a reading module;

FIG. 6 is a schematic block diagram of the tag shown in FIG. 2 and a reader;

FIG. 7 illustrates reading out data from the tag using a capacitance bridge;

FIG. 8 is a graph showing read out states;

FIG. 9 illustrates a first example of an addressing arrangement;

FIG. 10 illustrates a second example of an addressing arrangement.

FIG. 11 is a plan view of another tag in accordance with the present invention, together with a set of driving lines and reading electrodes of an overlying reader;

FIG. 11a is an enlarged partial plan view of the tag shown in FIG. 11;

FIG. 12 is a schematic block diagram of the tag shown in FIG. 11 and a reader; and

FIG. 13 is a process flow diagram of a process of reading out data from the tag shown in FIG. 11.

### DETAILED DESCRIPTION OF EMBODIMENTS

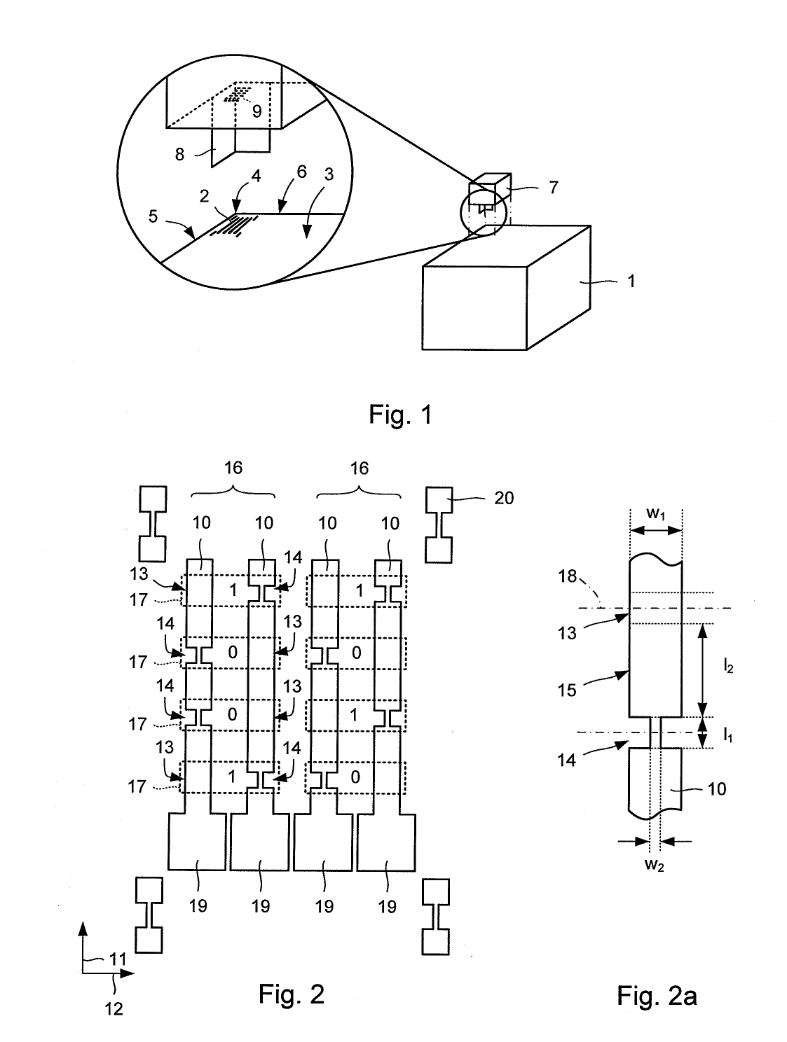

Referring to FIG. 1, an item 1, in this example packaging for a product (not shown), carries an electronic tag 2 in accordance with the present invention on a surface 3. The item 1 or part of the item 1 which carries the tag 2 is formed from an electrically-insulating material, such as cardboard or plastic. Thus, if the item 1 is conductive, then an insulating layer may be provided between the item 1 and the tag 2. In this and some of the other embodiments, the tag 2 is printed (e.g. by offset printing) onto the item 1 using conductive ink. However, in some embodiments, the tag 2 is applied in other ways, such as by transferring a conductive foil pattern onto the item 1 or by etching a conductive layer on the surface 3 of the item 1. In some embodiments, the item 1 may be the product.

The tag 2 is located adjacent (e.g. within a few centimetres) to a corner 4 of the packaging 1 where first and second edges 5, 6 meet. In this example, the tag 2 is located on an upper face 3. Locating the tag 2 close to a corner 4 or edge 5, 6 can help a user to align more easily a tag reader 7 to the tag 2 so as to enable the tag 2 to be read. For example, the tag reader 7 may be provided with a set of edges 8 for positioning the tag reader 7 relative to the item 1 in such a way so as to align tag reading elements 9 of the tag reader 7 with the tag 2. Notwithstanding this, the tag 2 need not be located at or close to a corner 4 or edge 5, 6. For example, the tag 2 may be provided with a set of markers 37 (FIG. 6) and the tag reader 7 may be provided with a corresponding set of sensors 36 (FIG. 6) and means for providing feedback (e.g. an electrical signal to a machine or audio/visual signal to a user) for aligning the tag reading elements 9 to the tag 2.

Referring to FIG. 2, the tag 2 includes a plurality of conductive tracks 10 extending in a first, longitudinal direction 11 and spaced apart along a second, transverse direction 12, e.g. side by side in columns. Each track 10 includes relatively wide portions 13 and/or relatively narrow portions 14.

As shown in FIG. 2a, the relatively wide portions 13 have a first width, w₁, and the relatively narrow potions 14 have a second, different width, w₂. In this example, w₁=5 mm and w₂=0.5 mm. However, the widths may be smaller and may be of the order of 10 or 100 μm. The width of the wide portion 13 may be at least 10 times the width of the narrow portion 14, i.e. w₁≧10 w₂. The wide and narrow portions 13, 14 have a length, l₁, and are separated by a connecting portion 15 of length, l₂. In this example, l₁=0.5 mm and l₂=20 mm. As shown in FIG. 2a, the connecting portions 15 have the same width as the wide portions 13, i.e. w₃=w₁.

Referring again to FIG. 2, the tracks 10 can be arranged into n-adjacent, non-overlapping pairs 16. In this example, n=2. In each pair 16, m-data-encoding sections 17 are arranged along the tracks 10 to provide pairs of complementary wide and narrow portions 13, 14. In this example, m=4. In particular, if one track 10 in a pair 16 has a narrow potion 14 within a section 17, then the other track 10 in the pair 16 has a wide potion 13 within the same corresponding section 16. Thus, if a line 18 crosses (e.g. perpendicularly) the pair of tracks 10 across in these sections 17, then the line 18 crosses a narrow portion 14 in one track 10 and a wide portion 13 in the other track 10. Sections 17 and corresponding portions of track 10 may be defined in terms of distance from one end of the track. For example, portions of different track may be considered to be corresponding if they lie at the same distance or with the same range of distances from the same end of each track.

This can be used to encode data in the tag 2 in the form of binary digits ‘0’ and ‘1’. For each given section 17, a first combination, for example in which a right-hand track has a wide portion 13 and a left-hand track has a narrow portion 14, is used to encode a ‘0’ and a second combination, for example in which a left-hand track has a wide portion 13 and a right-hand track has a narrow portion 14, is used to encode a T.

Data can be read out of the tag 2 by taking a measurement (or measurements) to determine which track 10 contains the wide portion 13 and which track 10 contains the narrow portion 14 in a section 17 in a pair 15. The measurement(s) are based on a property whose value depends on the width of the track 10, such as resistance or capacitance. As will be explained in more detail later, a difference measurement can used to identify the combination. This can have the advantage of avoiding measuring absolute values of the measurable property thereby providing improved immunity to noise and/or variations arising during track fabrication.

Each track 10 includes a read pad 19, which in this case is located at one end of the track 10. However, the read pad 19 may be located between the ends of the track 10, for example in the middle of the track 10. Furthermore, read pads 19 for some tracks 10 may be located at one end of the track 10 (for example at a bottom end as shown in FIG. 2) and pads 19 for other tracks may be located at the other end of the track 10 (for example at a top end). Each track 10 may include two read pads 19, for example at each end, or more than two read pads 19, for example at regular intervals along the track 10.

As shown in FIG. 2, the tag 2 comprises two pairs 16 of tracks 10, i.e. n=2, having four data-encoding sections 17, i.e. m=4, thereby allowing 8 bits, i.e. n×m, to be stored. However, there may be a greater number of pairs 16 of tracks 10, i.e. n>2. For example, there may be four pairs of track 10, i.e. n=4, or more than four pairs 16 of tracks 10, i.e. n>4.

There may be more data-encoding sections 17, i.e. m>4. The number of encoding sections 17 may be limited by the sheet resistance of material used to form the tracks 10. However, multiple read pads 19 may help to minimise separation between a data-encoding section 17 and a read pad 19.

The tag 2 may include patterned regions 20 for providing electrical test structures and/or registration marks. In this example, the patterned regions 20 are dumbbell shaped and allow reference values of resistance and/or capacitance to be measured.

The tag 2 is applied by printing conductive ink onto the packaging 1 and curing the ink, for example by simply allowing a solvent to evaporate, heating or exposing the ink to ultraviolet light. The ink may be metallic, e.g. containing particles of silver, carbon-based or organic. The cured ink has a thickness, t, of the order of 10 μm and a sheet resistance of the order of 100 kΩ/square. The ink may be thinner, e.g. of the order of 1 μm, or thicker, e.g. of the order of 100 μm and may have a lower sheet resistance.

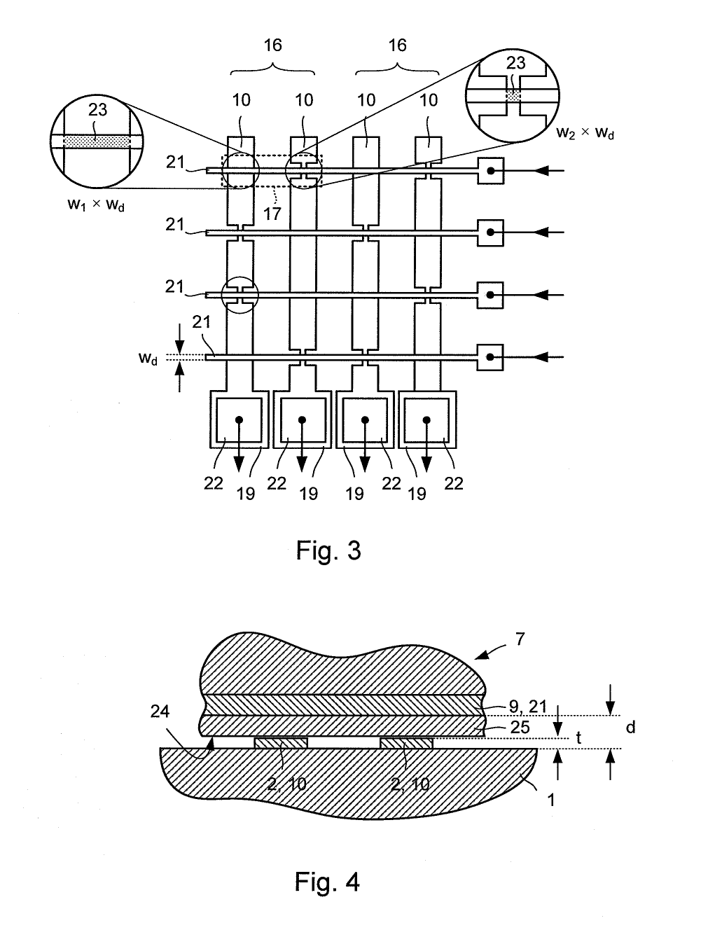

Referring to FIGS. 3, 4, 5 and 6, data is read out from the tag 2 by placing the tag reader 7 over the tag 2 thereby coupling tag reading elements 9 with the tag 2. In this and some other embodiments, the tag reader 7 and the tag 2 are capacitively coupled. However, in some embodiments, the tag reader 7 and the tag 2 may be resistively coupled by placing the tag reading elements in direct, i.e. electrical, contact with tag 2.

The tag reading elements 9 include a plurality of elongate conductive tracks 21 (herein referred to as “drive lines”) which, when the tag reader 7 and tag 2 are correctly aligned, cross the conductive tracks 10 of the tag 2. The tag reading elements 9 also include a plurality of read electrodes 22 which overlie the read pads 19 of the tag 2.

The drive lines 21 have a uniform width, w_{d}, for example 0.5 mm. Therefore, where the drive lines 21 cross the tracks 10, regions 23 are defined having a relatively large area (w₁×w_{d}) or relatively small area (w₂×w_{d}) depending on whether it crosses a wide portion 13 or narrow portion 14 of a track 10.

The tag reading elements 9 do not come into electrical contact with the tag 2. For example, as shown in FIG. 4, the face 24 of the tag reader 7 which is placed against the tag 2 for reading is provided with an electrically-insulating coating 25, such as a layer of plastic. The coating 25 may help to separate the elements 9 and tag 2 by a constant distance, d, and so help to provide uniform reading conditions. The coating 25 may also help to reduce wear of the reading elements 9. The separation, d, is about 100 μm. However, the separation may be less or greater.

Additionally or alternatively, the tag 2 may be provided with an electrically-insulating coating (not shown), such as a layer of ink. Not only can the layer serve the same purpose(s) as the coating 25 on the tag reader 7, but also help to conceal the underlying tag 2.

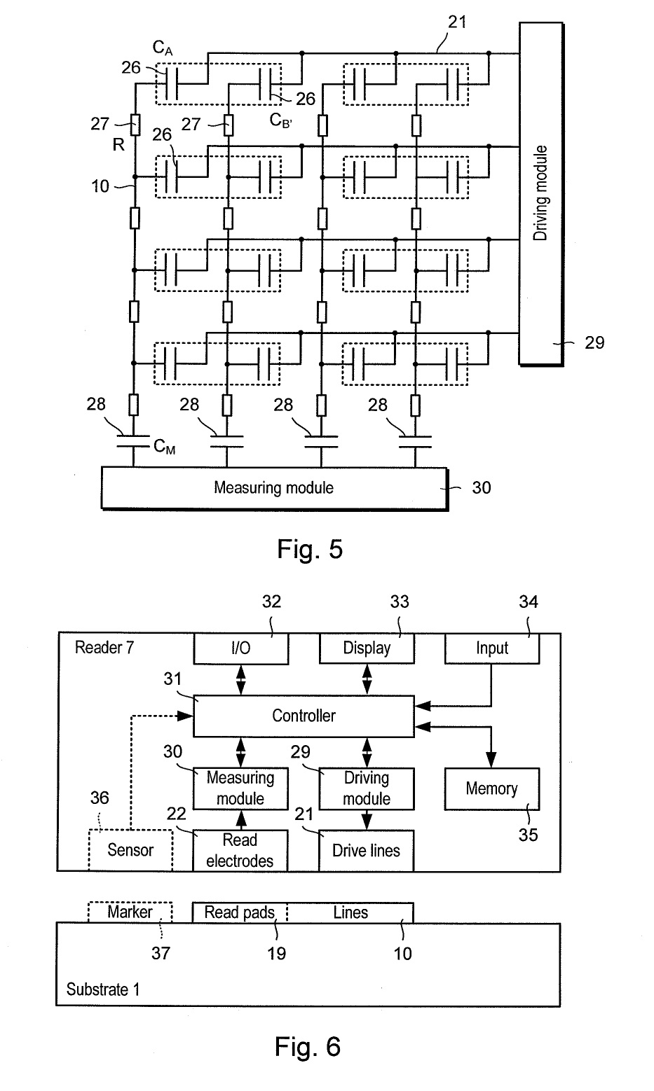

Referring in particular to FIG. 5, when coupled, the tag 2 and tag reader 7 form an array of capacitive elements 26. The capacitive elements may be interconnected by resistive elements 27 arising from the track 10. The tag 2 and reader 7 also form a row of capacitive elements 28 via which the capacitive and resistive elements 26, 27 can be measured.

For example, C_{A} and C_{B} may have values of the order of 0.1 to 10 pF, preferably of the order of 1 pF, and C_{M} may have a (larger) value of the order of 10 pF to 10 nF, preferably of the order of 1 nF. R may have a value of the order of 1 kΩ to 100 MΩ, preferably of the order of 1 MΩ.

A driving module 29 is used to apply time-varying input signals to each line 21 of the reader 7. As will be explained in more detail later, the lines 21 can be driven simultaneously by applying a signal of different frequency to each respective line 21. However, the lines 21 can be driven singly in a given sequence. A reading module 30 is used to measure output signals from the data-encoding sections 17 when the driving module 29 applies the input signals. As will be explained later, the reading module 30 measures differences in impedance between tracks 10 in a pair 16 and different sections 17 are probed by measuring impedance at different frequencies.

Referring to FIG. 6, the reader 7 includes the drive lines 21, the read electrodes 22, the driving module 29, the reading module 30, a controller 31, an optional data input/output interface 32, a display 33, an optional user input device 34 and memory 35. The reader 7 may also include sensor(s) 36 for aligning the tag reader 7 with registration marks 37 on the tag 2. The controller 31 controls operation of the other elements of the reader 7 shown in FIG. 6. For example, the controller 31 may receive an instruction from the user via input device 34 to read the tag 2. Additionally or alternatively, the controller 31 may instruct the driving and reading modules 29, 30 to co-operate to check periodically for the presence of a tag 2, for example testing whether the patterned regions 20 of the tag 2 are present. The controller 31 instructs the driving module 29 to provide input signals to the drive lines 21 and the reading module 30 to measure output signals from the read electrodes 22. The controller 31 receives a result of the measurement, for example in the form of the encoded number, and may convert the number into, for example a product number and/or description which can be understood by the user. The controller 31 outputs the number or product information to the display device 33.

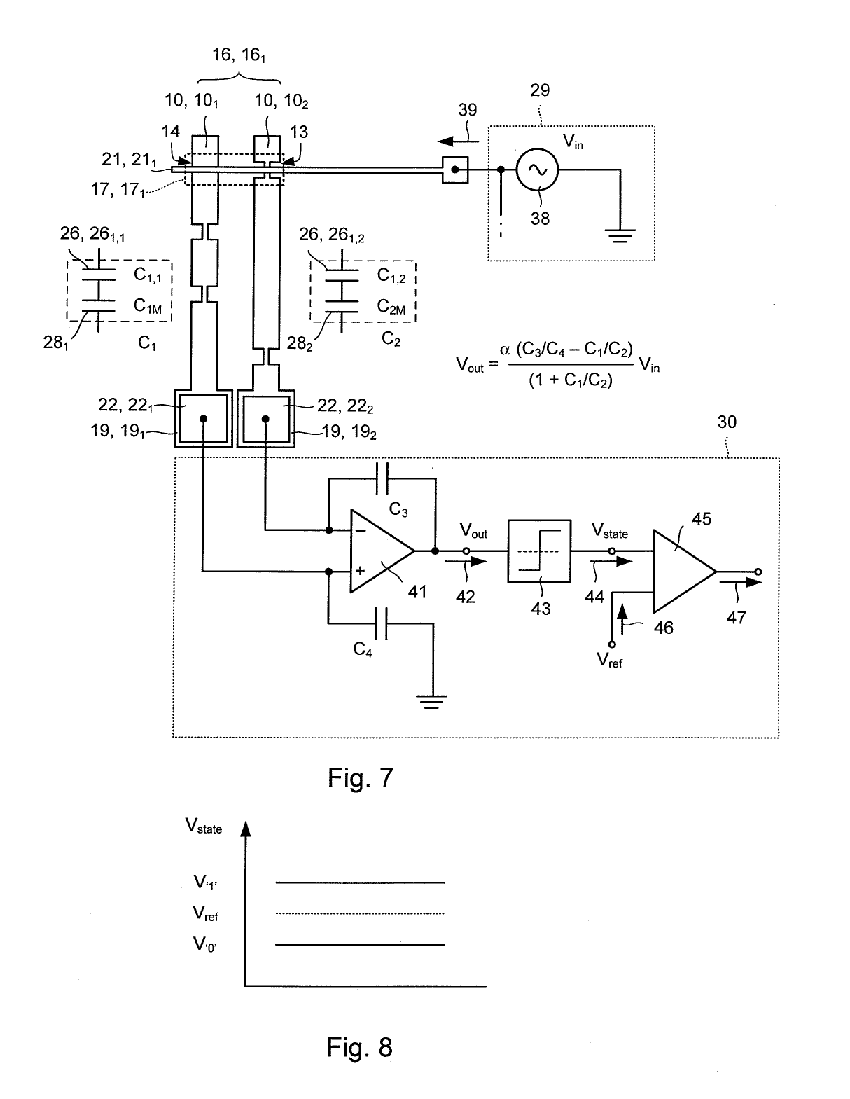

Referring to FIG. 7, the driving module 29 includes a voltage source 38 which applies a time-varying input signal 39 to the line 21 at a frequency, f, and peak amplitude, V. In this example, f=10 kHz and Vᵢₙ=2.5 V. As will be explained in more detail later, different input signals 39 can be applied to each different line 21 simultaneously.

As shown in FIG. 7, a capacitor 26 created by a track 10 and a drive line 22 and a capacitor 28 created by a read pad 19 and a read electrode 22 are formed in series. The values of capacitance of these capacitors 26, 28 may be represented by a lumped capacitance.

For example, taking the example of a pair 16, of tracks 10₁, 10₂, a first capacitor 26, having a capacitance C_{1,1} is created by a first track 10, and a first drive line 22, and a second capacitor 26₂ having a capacitance C_{1,2} is created by a second track 10₂ and the drive line 22. First and second coupling capacitors 28₁, 28₂ having capacitances, C_{1M} and C_{2M} are created by first and second read pads 19₁, 19₂ and corresponding read electrodes 22₁, 22₂ respectively. A value of a first lumped capacitance C₁ can be obtained for the first capacitor 26₁ and the first coupling capacitor 28₁. Likewise, a value of a second lumped capacitance C₂ can be obtained for the second capacitor 26₂ and the second coupling capacitor 28₂.

The values for the first and second coupling capacitances are substantially the same, i.e. C_{1M}=C_{2M}. Thus, if values for C₁ and C₂ are compared, then any difference between the values primarily arises from differences in capacitance C_{1,1}, C_{1,2} for the first and second capacitors 26₁, 26₂.

For each data-encoding section 17, the overlapping region 23 (FIG. 3) for one track 10 is larger than the overlapping region 23 (FIG. 3) of the other track 10 by virtue of the fact that one track 10 has a wide section 13 and the other track has a narrow section 14. Using a parallel plate capacitor model, capacitance is directly proportional to the area of the capacitor plates (C=εᵣεₒA/d where A is plate area, d is plate separation, εᵣ is relative permittivity and εₒ is permittivity of free space). Thus, the capacitance C₁ for the first track 10, is greater than the capacitance C₂ of the second track 10₂.

Absolute values of the capacitances C₁, C₂ need not be measured. Instead, a difference may be measured using a capacitance bridge having reference capacitors 40 having values of capacitance C₃ and C₄.

In this and some embodiments, the difference is measured using an operational amplifier 41 having gain, α. The operational amplifier 41 produces an output signal 42 having a peak voltage, Vₒᵤₜ. Thus, the values of peak voltage for the input and output signal are related by:

$${V}_{out} = α \frac{( {C}_{3} / {C}_{4} - {C}_{1} / {C}_{2} )}{( 1 + {C}_{1} / {C}_{2} )} {V}_{in} \qquad ( 1 )$$

The output signal 42 is passed through a rectifier 43 to produce a rectified signal 44 having a magnitude Vₛₜₐₜₑ. The first and second configurations of wide and narrow sections 13, 14 (FIG. 2a) which encode ‘0’ and ‘1’ respectively produce two different values for the rectified signal 44, namely Vₛₜₐₜₑ=V_{‘0’} and Vₛₜₐₜₑ=V_{‘1’}, as shown in FIG. 8. Optionally, the rectified signal 44 is then passed to a comparator 45 for comparison against a reference signal 46 having a magnitude V_{ref} to produce an output signal 47.

Thus, a difference measurement between tracks 10 for a data-encoding section 17 driven by the line 21 yields a value V_{‘0’} or V_{‘1’}, indicative of the stored value ‘0’ or ‘1’ respectively.

Two different addressing arrangements can be used.

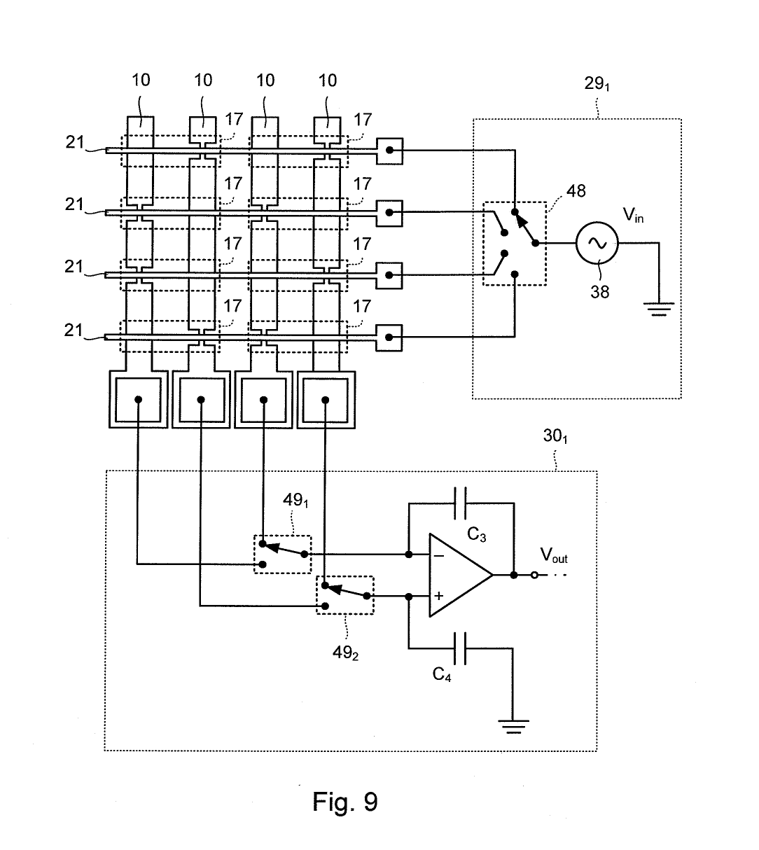

Referring to FIG. 9, in a first addressing arrangement, each data-encoding section 17 can be individually addressed by selecting a pair of tracks 10 and a drive line 21. Thus, a driving module 29₁ may include an m-pole switch 48 which sequentially connects the time-varying voltage source 38 to each line 21. A reading module 30, also includes a pair of n-pole switches 49₁, 49₂ for switching the inputs of the operational amplifier 41 to each pair of tracks 10. While a given line 21 is driven, a series of measurements for each pair of tracks 10 is taken, i.e. n measurements are taken. Once the measurements for a given line 21 have been taken, then the next line 21 is driven and another series of measurements are taken.

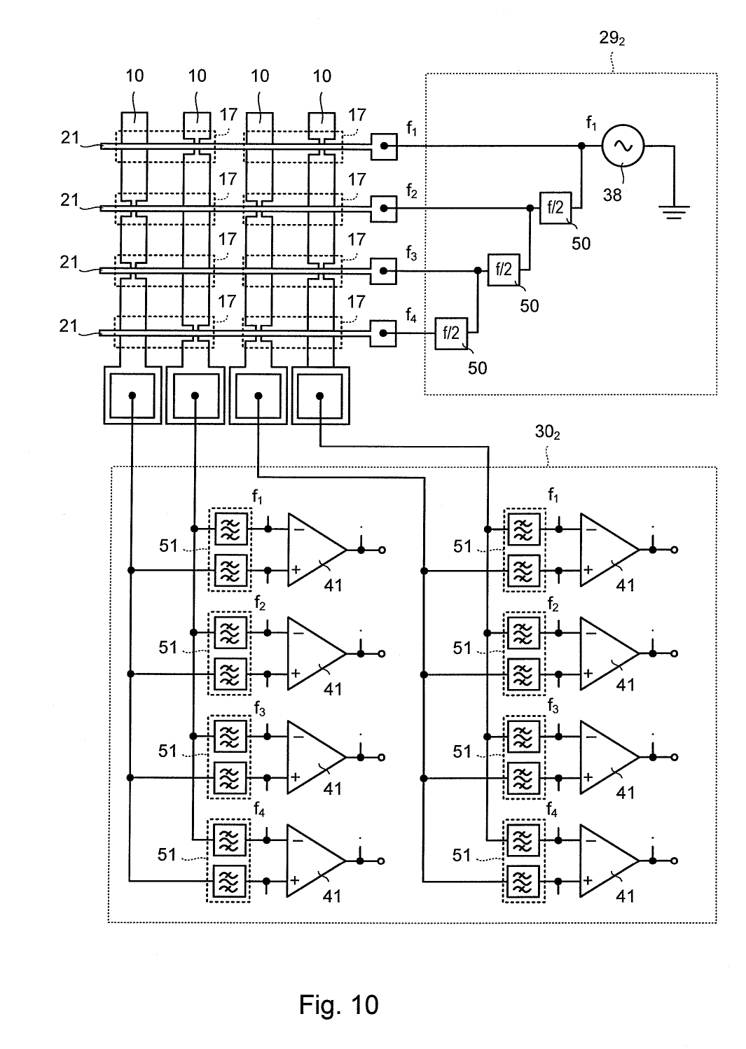

Referring to FIG. 10, in a second addressing arrangement, each data-encoding section 17 can be individually, but simultaneously addressed, using a cascade of frequency dividers 50 so that an input signal 39 having a different frequency, f₁, f₂, f₃, f₄, is applied to each drive line 21, and using an array of bandpass filters 51 and operational amplifiers 41. Each pair of bandpass filters 51 which is attached to the same pair of tracks 10 is tuned to one of frequencies, f₁, f₂, f₃, f₄, of the input signals. For example, a first pair of bandpass filters 51 are tuned to a first frequency f₁, a second pair of bandpass filers 51 are tuned to a second frequency f₂=f₁/2 etc. Reference capacitors have been omitted from FIG. 10 for clarity.

In this and some other embodiments, the tag reader 7 is stationary with respect to the tag 2 while it carries out one or more measurements, i.e. during reading. In some embodiments, the tag reader 7 may move slowly relative to the tag during reading.

In the examples described earlier, data read out relies primarily on measuring values of capacitance. However, if the tag 2 is fabricated using an ink having a high value of sheet resistance (e.g. >100 kΩ/square) and/or if the tracks 10 are thin (e.g. <100 μm), then the resistance of the tracks 10 (FIG. 1) can become significant. In this case, data read out can involve measuring impedance which includes resistive and capacitive contributions.

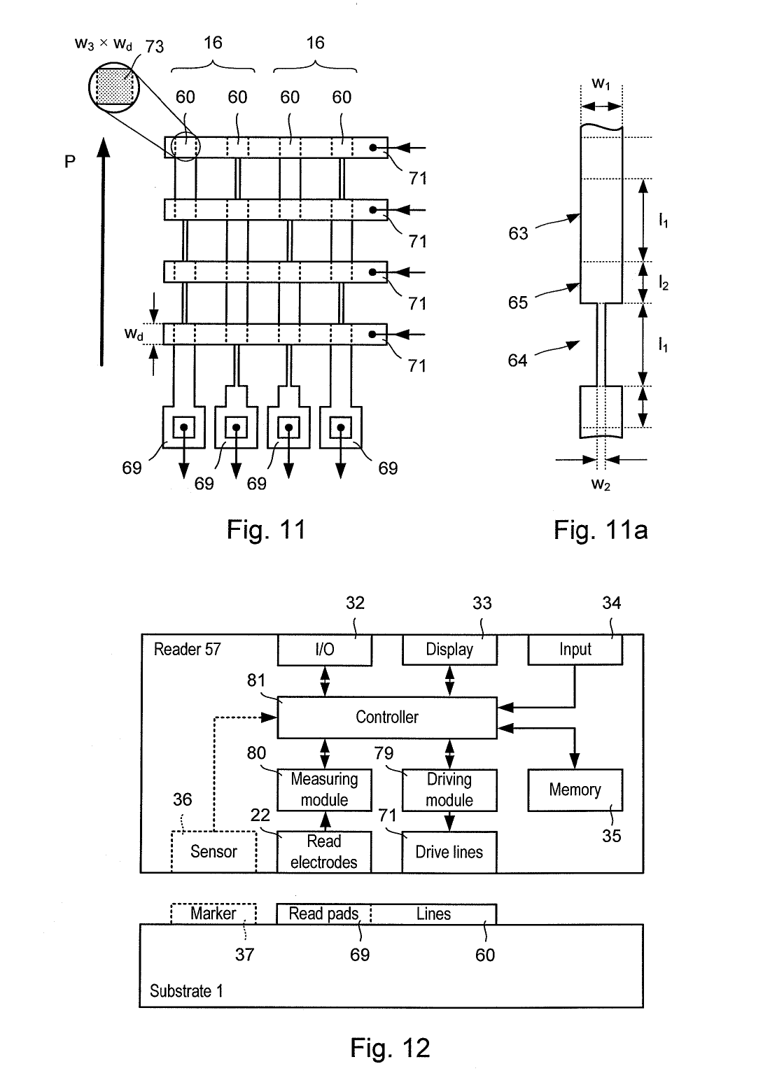

Referring to FIGS. 11 and 11a, another tag 52 is shown. The tag 52 is similar to the tag 2 described earlier. For example, the tag 52 comprises a plurality of conductive tracks 60 extending in a first direction 61 and spaced apart along a second, transverse direction 62. Each track 60 includes relatively wide portions 63 and/or relatively narrow portions 64. As shown in FIG. 11a, w₁=5 mm, w₂=0.5 mm, l₁=10 mm and l₂=5 mm.

Similar to the tag 2 described earlier, the tracks 60 are arranged into n-adjacent, non-overlapping pairs 66. In each pair 66, m-data-encoding sections 67 are arranged along the tracks 60 to provide pairs of complementary wide and narrow portions 63, 64. In this example, n=2 and m=4. Each track 60 includes a read pad 69, which in this case is located at one end of the track 10.

Similar to the tag 2 described earlier, the tag 52 is applied by printing conductive ink onto packaging 1 (FIG. 1) and curing the ink.

Referring also to FIG. 12, another tag reader 57 is used which is similar to the tag reader 7 described earlier. Elements of the tag reader 57 which operate in the same way as the tag reader 7 described earlier are identified using the same reference numerals.

Referring in particular to FIG. 11, the tag reader 57 differs from the tag reader 7 described earlier in that drive lines 71 cross connecting regions 65 of the tag 52 between the wide and narrow portions 63, 64 of the tracks 10. The connecting regions 65 have the same width w₃. Thus, regions 73 where the drive lines 71 cross the tracks 10 each have the same area, namely w₃×w_{d}). In this example, w₃=w₁ and w_{d}=5 mm.

An addressing arrangement can be used similar to the first addressing arrangement described earlier. However, read out begins with the data-encoding sections 67 closest to the read pads 69 (in this example identified using an index, i=1) and moves to the next closest data-encoding section (i=2) and so on in the direction of the arrow P. This is because, as will be explained in more detail, read out of an i-th data encoding section 67 depends on a result of an (i−1)-th data-encoding section 67.

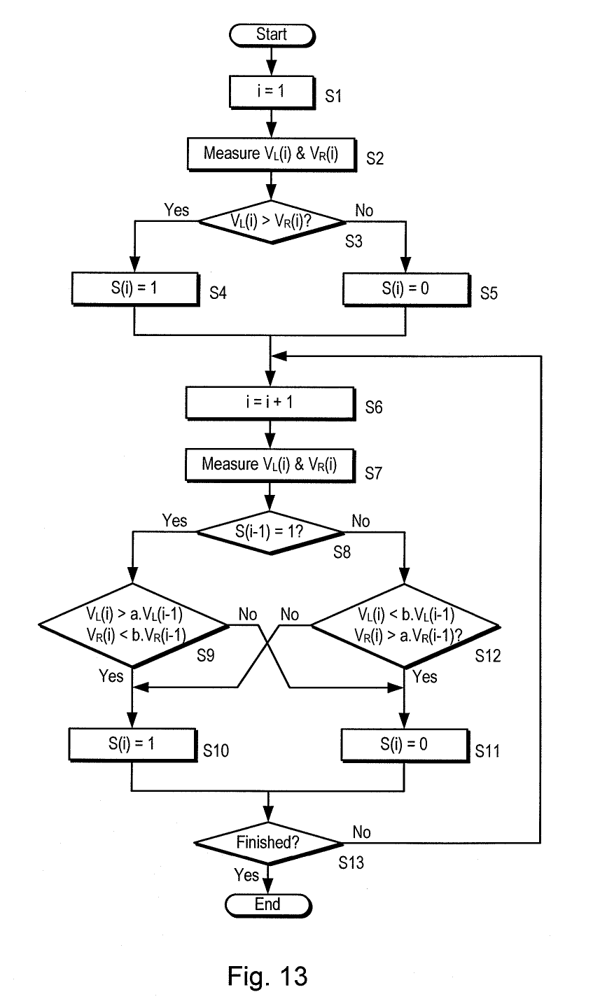

Referring also to FIG. 13, a process of reading the tag 52 using the tag reader 57 will now be described.

Starting with the drive line 71 closest to the read pad (step S1), the driving module 79 applies an input signal to the drive line 71 and the measuring module 80 measures peak values of output signals for each pair of tracks 10, namely V_{L}(i) and V_{R}(i), using a voltage reading module (not shown) (steps S2 & S3) and reports these values to the controller 81, which stores the values and the state S(1) found by taking the difference and determining which track is more resistive (steps S4 & S5).

The same read process is performed for each pair of tracks.

The next drive line 71 is selected (step S6) and the measuring module 80 measures peak values of output signals for each pair of tracks 10 (steps S7) and reports these values to the controller 81.

Using the previous values, namely V_{L}(i−1) and V_{R}(i−1), and the state of the previous data-encoding section 67, namely S(i−1), the controller 81 compares the current values, namely V_{L}(i) and V_{R}(i), with the previous values, namely V_{L}(i−1) and V_{R}(i−1), adjusted for the proportional drop in voltage taking into account a wider, less resistive section, by a factor a, and a narrower, more resistive section, by a factor b, where 0<a<b<1 (steps S8 to S12).

The controller 81 stores the voltage values and the state S(i) (steps S13 and S14).

The process continues until all data encoding sections 67 have been read (step S15).

It will be appreciated that many modifications may be made to the embodiments hereinbefore described. For example, a track may include portions having three or more different widths.

The tag reader 9 may be differently configured such that drive lines become read lines and vice versa. Thus, the pads 19 may be driven by a driving module 27, signals read by the lines 21 and fed to reading module 30.

The tag need not lie on an outer surface of the packaging, but may lie on an inner surface of the packaging or even be embedded, for example in a “glue flap” of a carton. Thus, the tag may be read through the packaging.

1. An electronic tag comprising a plurality of elongate conductive tracks extending in a first, longitudinal direction and spaced apart along a second, transverse direction, each track including relatively wide and relatively narrow portions, the plurality of conductive tracks including at least one pair of conductive tracks providing at least one data-encoding section in which a portion of one track is relatively narrow and a corresponding portion of the other track is relatively wide.

2. A tag according to claim 1, wherein the at least one pair of conductive tracks are adjacent.

3. A tag according to claim 1, wherein the conductive tracks comprise conductive ink.

4. A tag according to claim 1, wherein the plurality of conductive tracks comprise at least two pairs of tracks conductive tracks.

5. A tag according to claim 1, wherein the plurality of conductive tracks comprise at least four pairs of tracks conductive tracks.

6. A tag according to claim 1, wherein the relatively wide portion is at least 10 times the width of the relatively narrow portion.

7. A tag according to claim 1, wherein the relatively narrow portion has a width no more than 500 μm.

8. A tag according to claim 1, wherein the at least one pair of conductive tracks is configured to provide at least two data-encoding sections.

9. A tag according to claim 1, wherein the at least one pair of conductive tracks is configured to provide three, four or five data-encoding sections.

10. A tag according to claim 1, wherein each track includes at least one further portion having a width different from the relatively wide and narrow portions.

11. A product or packaging for a product having a surface, wherein the surface supports an electronic tag according to claim 1.

12. A device for reading an electronic tag comprising:
a substrate extending in first and second transverse directions;
at least one elongate conductive line, supported on the substrate, extending in the second direction;
a plurality of electrodes, supported on the substrate, spaced along the second direction and spaced from the at least one conductive line in the first direction, the plurality of electrodes including at least one pair of electrodes;
a signal generator arranged to apply a time-varying signal to the one of the at least one elongate conductive line; and
a circuit for receiving a respective signal from each electrode of the pair of electrodes and to output a signal dependent upon a difference between the signals.

13. A device according to claim 12, comprising:
at least two elongate conductive lines, supported on the substrate, extending in the second direction.

14. A device according to claim 12, comprising:
three, four or five elongate conductive lines, supported on the substrate, extending in the second direction.

15. A device according to claim 13, comprising:
switching means configured to apply the time-varying signal to the conductive lines in sequence.

16. A device according to claim 13, comprising:
means for applying a respective time-varying signal to each conductive line each time-varying signal have a different frequency.

17. A device according to claim 16, wherein the circuit is arranged to measure more than one signal component between each electrode of the pair of electrodes, each signal component having a different frequency.

18. A method of fabricating an electronic tag comprising:
providing a plurality of elongate conductive tracks extending in a first, longitudinal direction and spaced apart along a second, transverse direction, each track including relatively wide and relatively narrow portions, the plurality of conductive tracks including at least one pair of conductive tracks; and
arranging the at least one pair of conductive tracks to provide at least one data-encoding section in which a portion of one track is relatively narrow and a corresponding portion of the other track is relatively wide.

19. A method according to claim 18, wherein providing the plurality of conductive tracks comprises printing the plurality of elongate conductive tracks using a conductive ink.

20. A method of reading an electronic tag comprising a plurality of elongate conductive tracks extending in a first, longitudinal direction and spaced apart along a second, transverse direction, each track including relatively wide and relatively narrow portions, the plurality of conductive tracks including at least one pair of conductive tracks providing at least one data-encoding section in which a portion of one track is relatively narrow and a corresponding portion of the other track is relatively wide, the method comprising:
placing at least one elongate conductive line extending in the second direction over the at least a pair of conductive tracks inside the data-encoding section;
placing at least two electrodes over the conductive tracks outside the data-encoding section;
applying a time varying signal to the elongate conductive line; and
determining an output signal dependent upon a difference between signals taken from the two electrodes.

21. A method of reading an electronic tag comprising a plurality of elongate conductive tracks extending in a first longitudinal direction and spaced apart along a second, transverse direction, the plurality of conductive tracks including at least one pair of conductive tracks providing at least one data-encoding section in which a portion of one track is relatively narrow and a corresponding portion of the other track is relatively wide, the method comprising:
placing at least one elongate conductive line extending in the second direction over the at least a pair of conductive tracks one side of the data-encoding section;
placing at least two electrodes over the conductive tracks on the other side of the data-encoding section such that the data-encoding section lies between the at least one elongate conductive line and the electrodes;
applying a time varying signal to the elongate conductive line; and
determining an output signal dependent upon a difference between signals taken from the two electrodes.

22. A method according to claim 20, further comprising:
keeping a tag reader stationary with respect to the tag.
